(19) United States
(12) Patent Application Publication
(10) Pub. No.: US 2015/0357455 A1
(43) Pub. Date: Dec. 10, 2015

(54) SEMICONDUCTOR DEVICE AND METHOD OF MANUFACTURING THE SAME

(71) Applicant: Kabushiki Kaisha Toshiba, Tokyo (JP)

(72) Inventors: Tetsuya Ohno, Nomi Ishikawa (JP); Akira Yoshioka, Nomi Ishikawa (JP)

(21) Appl. No.: 14/643,809

(22) Filed: Mar. 10, 2015

(30) Foreign Application Priority Data
Jun. 10, 2014 (JP) 2014-119846

(51) Int. Cl. H01L 29/778; H01L 29/10; H01L 29/66

(52) U.S. Cl. CPC H01L 29/7786; H01L 29/66462; H01L 29/1095

(57) ABSTRACT

In one embodiment, a semiconductor device includes a first semiconductor layer of a first conductivity type or an intrinsic type, and a second semiconductor layer of a second conductivity type provided on the first semiconductor layer. The device further includes a third semiconductor layer of the first conductivity type or an intrinsic type provided on the second semiconductor layer, and a fourth semiconductor layer provided on the first semiconductor layer. The device further includes a fifth semiconductor layer of the second conductivity type provided on the fourth semiconductor layer, and a control electrode provided on the second semiconductor layer through an insulating layer and electrically connected to the fifth semiconductor layer.

### CROSS REFERENCE TO RELATED APPLICATION

This application is based upon and claims the benefit of priority from the prior Japanese Patent Application No. 2014-119846, filed on Jun. 10, 2014, the entire contents of which are incorporated herein by reference.

### FIELD

Embodiments described herein relate to a semiconductor device and a method of manufacturing the same.

### BACKGROUND

A field effect transistor using a nitride semiconductor material has excellent material properties such as a large band gap, a high electric field strength, and a high saturation velocity. For example, it is known that a two-dimensional electron gas (2DEG) layer of a high concentration and a high electron mobility is generated spontaneously on an interface between a gallium nitride (GaN) and an aluminum gallium nitride (AlGaN) due to polarization effect. At the interface, these layers are hetero-joined. An example of a transistor making use of 2DEGs due to this heterojunction is a heterojunction field effect transistor (HFET). The HFET shows great promise as a next-generation transistor such as a power control device and a switching device that need high-power, high-voltage, and high-temperature operations.

There are various structures of the HFET. Each of the structures has an appropriate application that can make use of its features. Among these structures, a vertical structure is suitable to reduce an on-resistance and to increase a breakdown voltage, and is suitable for a switching device or the like. However, even with the vertical structure, the on-resistance per unit area is increased as the area of a cell (cell pitch) is increased, which makes the HFET unsuitable for the switching application. It is desired not only to reduce the cell pitch, but also to exert an operation of an enhancement type while enabling both an excellent pinch-off and a high electron mobility that serve to reduce the on-resistance as well.

### BRIEF DESCRIPTION OF THE DRAWINGS

FIG. 1 is a cross sectional view showing a structure of a semiconductor device of a first embodiment;

FIGS. 2A to 5C are cross sectional views showing a method of manufacturing the semiconductor device of the first embodiment;

FIGS. 6A to 6C are cross sectional views and a plan view showing a structure of a semiconductor device of a second embodiment;

FIGS. 7A to 10B are cross sectional views and plan views showing a method of manufacturing the semiconductor device of the second embodiment;

FIG. 11 is a cross sectional view showing a structure of a semiconductor device of a third embodiment; and

FIGS. 12A to 13B are cross sectional views showing a method of manufacturing the semiconductor device of the third embodiment.

### DETAILED DESCRIPTION

Embodiments will now be explained with reference to the accompanying drawings.

In one embodiment, a semiconductor device includes a first semiconductor layer of a first conductivity type or an intrinsic type, and a second semiconductor layer of a second conductivity type provided on the first semiconductor layer. The device further includes a third semiconductor layer of the first conductivity type or an intrinsic type provided on the second semiconductor layer, and a fourth semiconductor layer provided on the first semiconductor layer. The device further includes a fifth semiconductor layer of the second conductivity type provided on the fourth semiconductor layer, and a control electrode provided on the second semiconductor layer through an insulating layer and electrically connected to the fifth semiconductor layer.

### First Embodiment

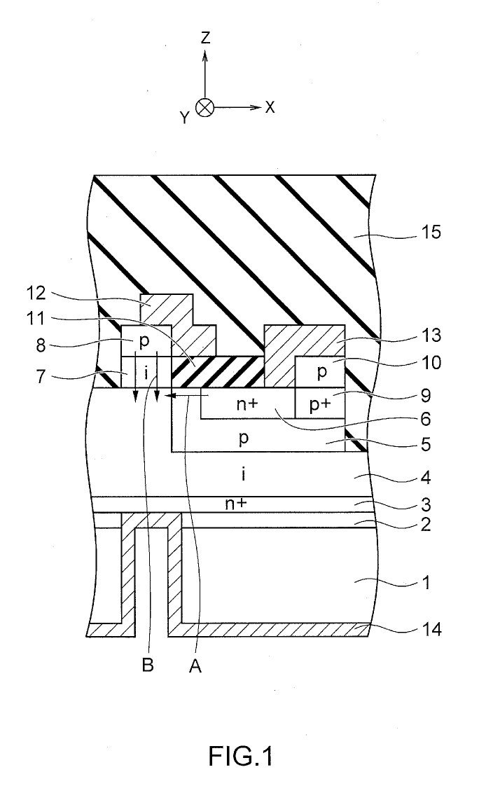

FIG. 1 is a cross sectional view showing a structure of a semiconductor device of a first embodiment. The semiconductor device in FIG. 1 includes a vertical transistor.

The semiconductor device in FIG. 1 includes a substrate 1, a buffer layer 2, a first n type contact layer 3, a first electron transport layer 4 as an example of a first semiconductor layer, a first p type semiconductor layer 5 as an example of a second semiconductor layer, a second n type contact layer 6 as an example of a third semiconductor layer, an electron supply layer 7 as an example of a fourth semiconductor layer, a second p type semiconductor layer 8 as an example of a fifth semiconductor layer, a p type contact layer 9, and a p type source layer 10.

Furthermore, the semiconductor device in FIG. 1 includes a gate insulator 11 as an example of an insulating layer, a gate electrode 12 as an example of a control electrode, a source electrode 13 as an example of a first electrode, a drain electrode 14 as an example of a second electrode, and an interlayer dielectric 15.

Reference characters n, p, and i shown in FIG. 1 denote semiconductor layers of an n type, p type, and i type (intrinsic type), respectively. The n type and the p type are examples of first and second conductivity types, respectively. The semiconductor layer of an i type means a semiconductor layer in which an n type impurity and a p type impurity are not intentionally contained. The semiconductor layer of the i type is also called an undoped semiconductor layer.

An example of the substrate 1 is a semiconductor substrate such as a silicon substrate. FIG. 1 shows an X direction and a Y direction that are parallel to the substrate 1 and orthogonal to each other, and a Z direction that is orthogonal to the substrate 1. In the present specification, a +Z direction is treated as an upward direction, and a −Z direction is treated as a downward direction. For example, the positional relationship between the substrate 1 and the interlayer dielectric 15 is expressed that the substrate 1 is positioned below the interlayer dielectric 15.

The buffer layer 2 is formed on the substrate 1. An example of the buffer layer 2 is a laminated film that includes an AlN (aluminum nitride) layer, an AlGaN layer, a GaN layer, and the like. Alternatively, examples of the buffer layer 2 also include one in which carbon atoms are doped.

The first n type contact layer 3 is formed on the buffer layer 2, and is in contact with the drain electrode 14. An example of the first n type contact layer 3 is an n+ type GaN layer with an n type impurity doped at a relatively high concentration. An example of this n type impurity is a silicon (Si) atom. The first n type contact layer 3 is provided for reducing a contact resistance with the drain electrode 14.

The first electron transport layer 4 is formed on the first n type contact layer 3. An example of the first electron transport layer 4 is an GaN layer of the i type, and may be an n-type GaN layer with an n type impurity doped at a concentration lower than that of the first n type contact layer 3. The first electron transport layer 4 is in contact with the lower portion and the side portion of the first p type semiconductor layer 5.

The first p type semiconductor layer 5 is formed on the first electron transport layer 4. An example of the first p type semiconductor layer 5 is a p type GaN layer with a p type impurity doped. An example of this p type impurity is a magnesium (Mg) atom. The first p type semiconductor layer 5 is in contact with the lower portion and the side portion of the second n type contact layer 6. A portion of the first p type semiconductor layer 5 in the vicinity of the gate electrode 12 is sandwiched between the first electron transport layer 4 and the second n type contact layer 6, and functions as a channel of the transistor.

The second n type contact layer 6 is formed on the first p type semiconductor layer 5, and is in contact with the source electrode 13. An example of the second n type contact layer 6 is an n+ type or i type GaN layer.

The electron supply layer 7 is formed on the first electron transport layer 4. An example of the electron supply layer 7 is an i type AlGaN layer.

The second p type semiconductor layer 8 is formed on the electron supply layer 7, and is in contact with the gate electrode 12. An example of the second p type semiconductor layer 8 is a p type AlGaN layer. The second p type semiconductor layer 8 of the present embodiment has a function of raising the potential of a channel on a heterointerface between the first electron transport layer 4 and the electron supply layer 7.

The p type contact layer 9 is formed on the first p type semiconductor layer 5, and is in contact with the side portion of the second n type contact layer 6. An example of the p type contact layer 9 is a p+ type GaN layer with a p type impurity doped at a concentration higher than that of the first p type semiconductor layer 5. The p type contact layer 9 is a layer for reducing a potential difference between the source electrode 13 and the first p type semiconductor layer 5 by being connected with the source electrode 13 via the p type source layer 10 to fix the potential of the first p type semiconductor layer 5.

The p type source layer 10 is formed on the p type contact layer 9, and is a layer for being in contact with the source electrode 13. The p type source layer 10 is provided for reducing a contact resistance with the source electrode 13.

The gate insulator 11 is formed on the first p type semiconductor layer 5 and the second n type contact layer 6. An example of the gate insulator 11 is a silicon dioxide film.

The gate electrode 12 is formed on the first p type semiconductor layer 5 and the second n type contact layer 6 through the gate insulator 11, and is electrically connected to the second p type semiconductor layer 8. An example of the gate electrode 12 is a metal layer. An example of this metal layer is a laminated film that includes at least any one of a platinum (Pt) layer, a nickel (Ni) layer, and a gold (Au) layer. The gate electrode 12 has a shape extending in the Y direction.

The source electrode 13 is formed on the second n type contact layer 6 and the p type source layer 10, and is in contact with the upper portion of the second n type contact layer 6, and the upper portion and the side portion of the p type source layer 10. The source electrode 13 has a shape extending in the Y direction.

The drain electrode 14 is formed under the first n type contact layer 3, and is in contact with the lower portion of the first n type contact layer 3. The drain electrode 14 has a shape extending in the Y direction. The drain electrode 14 of the present embodiment is further in contact with the lower portion and the side portions of the substrate 1, and the side portions of the buffer layer 2.

The interlayer dielectric 15 is formed on the substrate 1 such that the vertical transistor is covered therewith. An example of the interlayer dielectric 15 is a silicon dioxide film.

The second p type semiconductor layer 8 of the present embodiment has a function of raising the potential of a channel on a heterointerface between the first electron transport layer 4 and the electron supply layer 7. Therefore, when the transistor of the present embodiment is off, an energy level of a conduction band of the heterointerface becomes higher than the Fermi level thereof, and 2DEG in the channel is depleted. Therefore, the transistor of the present embodiment exerts an operation of an enhancement type in which it is brought into an off state when a gate voltage is not applied thereto.

On the other hand, when the transistor of the present embodiment is turned on, the upper surface of the first p type semiconductor layer 5 below the gate electrode 12 is channelized to be brought into a conduction state. Consequently, as shown by an arrow A, electrons flow from the second n type contact layer 6 to the first electron transport layer 4 via the first p type semiconductor layer 5. At the same time, positive holes are led from the second p type semiconductor layer 8 to the heterointerface as shown by arrows B, which generates electrons on the heterointerface. Consequently, electrons flow from the first electron transport layer 4 to the drain electrode 14.

In addition, the transistor of the present embodiment has a structure in which the source electrode 13 is disposed only on one side of the gate electrode 12. In addition, the first p type semiconductor layer 5 of the present embodiment pinches off the channel, thereby having a function as a barrier layer. According to the present embodiment, by disposing the source electrode 13 only on one side of the gate electrode 12, it is possible to pinch off the channel and to enhance the electron mobility of the transistor even if a bias voltage is zero. The cell structure of the present embodiment can have a shape such as a polygon, circle, and irregular shape.

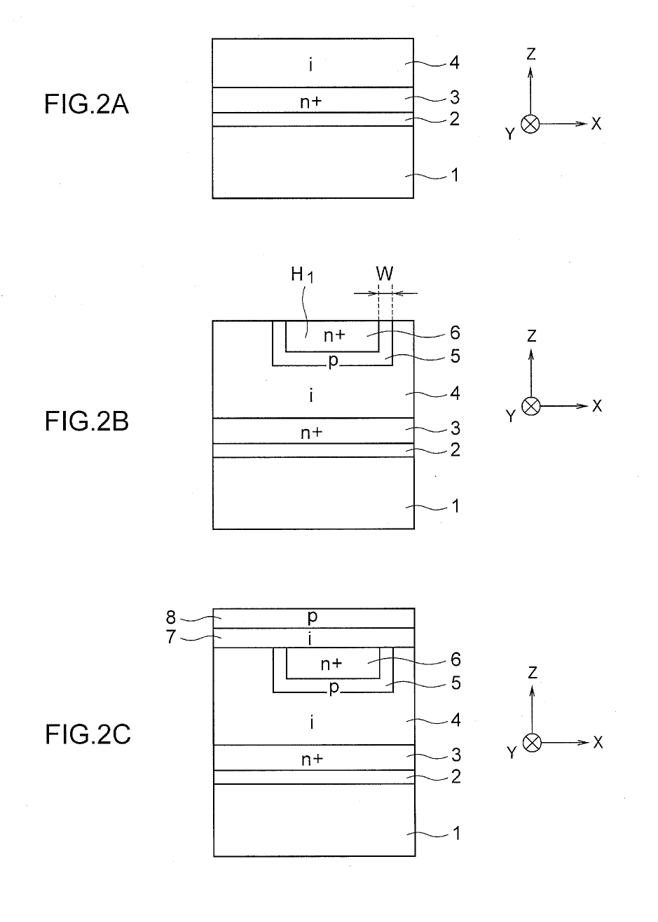

FIGS. 2A to 5C are cross sectional views showing a method of manufacturing the semiconductor device of the first embodiment.

First, as shown in FIG. 2A, the buffer layer 2, the first n type contact layer 3, and the first electron transport layer 4 are sequentially formed on the substrate 1.

Next, as shown in FIG. 2B, by means of lithography and RIE (Reactive Ion Etching), an opening H₁ is formed on the first electron transport layer 4. Next, the first p type semiconductor layer 5 is formed on the side portions and the lower portion of the opening H₁. Next, the second n type contact layer 6 is formed in the opening H₁ through the first p type semiconductor layer 5. Reference character W denotes the width of the uppermost portion of the first p type semiconductor layer 5 in the X direction. The width W may be any value as long as the first p type semiconductor layer 5 can be conductive by pinch-off and channelizing, and is for example, adjusted to about 0.02 μm to 1 μm. In addition, the second n type contact layer 6 may be formed by ion-implanting n type impurities to the first p type semiconductor layer 5. The thicknesses of the first p type semiconductor layer 5 and the second n type contact layer 6 cannot be sweepingly determined because they are changed considering the thickness of the first electron transport layer 4, the degree of Mg diffusion from the first p type semiconductor layer 5, and the like. When the thickness of the first electron transport layer 4 is, for example, 4 μm to 10 μm, the thickness of the first p type semiconductor layer 5 is adjusted to, for example, about 2 μm to 5 μm, and the thickness of the second n type contact layer 6 is adjusted to, for example, about 1 μm to 3 μm.

Next, as shown in FIG. 2C, the electron supply layer 7 is formed on the first electron transport layer 4, the first p type semiconductor layer 5, and the second n type contact layer 6. An example of the film thickness of the electron supply layer 7 is 25 nm. Next, the second p type semiconductor layer 8 is formed on the electron supply layer 7. An example of the film thickness of the second p type semiconductor layer 8 is 100 nm.

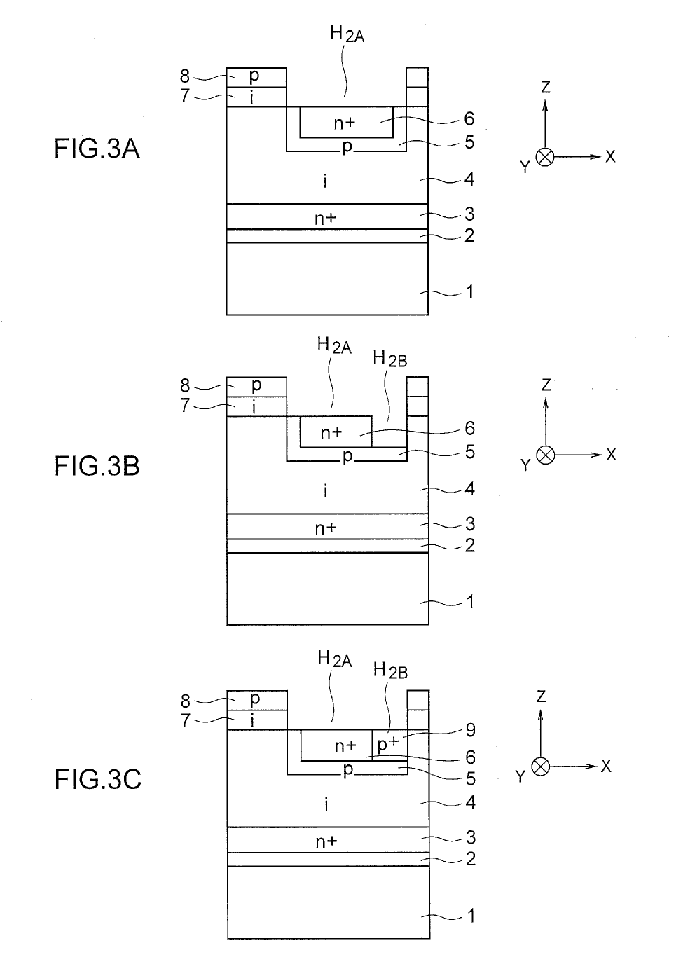

Next, as shown in FIG. 3A, by means of lithography and RIE, a first opening H_{2A} that penetrates the second p type semiconductor layer 8 and the electron supply layer 7, is formed.

Next, as shown in FIG. 3B, by means of lithography and RIE, a second opening H_{2B} is formed on the second n type contact layer 6 and the first p type semiconductor layer 5 in the first opening H_{2A}.

Next, as shown in FIG. 3C, the p type contact layer 9 is formed in the second opening H_{2B} in a state that areas other than the second opening H_{2B} are covered with resist masks. The thickness of the p type contact layer 9 is, for example, 0.01 μm to 3 μm.

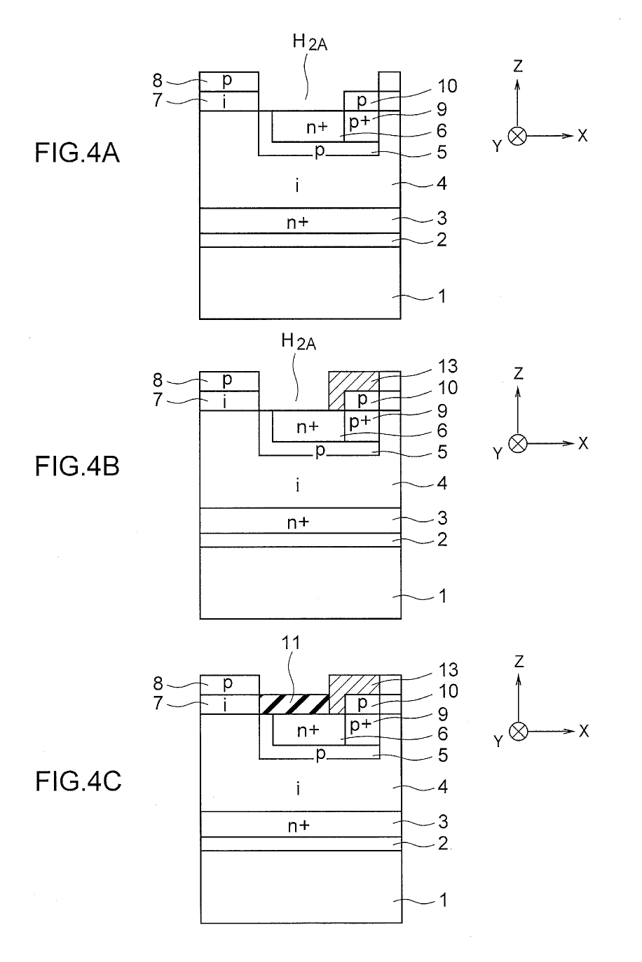

Next, as shown in FIG. 4A, the p type source layer 10 is formed on the p type contact layer 9 in a state that the areas other than the second opening H_{2B} are covered with the resist masks.

Next, as shown in FIG. 4B, the source electrode 13 is formed on the second n type contact layer 6 and the p type source layer 10 in the first opening H_{2A} in a state that areas other than the formation planned area of the source electrode 13 are covered with resist masks. An example of the material of the source electrode 13 is an ohmic electrode material, and the source electrode 13 is, for example, a laminated film that includes at least any one of an Al (aluminum) layer, Ti (titanium) layer, Ni (nickel) layer, and Au (gold) layer. Subsequently, the resist masks are removed through a liftoff process.

Next, as shown in FIG. 4C, the gate insulator 11 is formed on the first p type semiconductor layer 5 and the second n type contact layer 6 in the first opening H_{2A} in a state that areas other than the formation planned area of the gate insulator 11 are covered with resist masks. In order to flatten the gate insulator 11, the gate insulator 11 may be thinned by means of etching. An example of the film thickness of the gate insulator 11 is 10 to 50 nm.

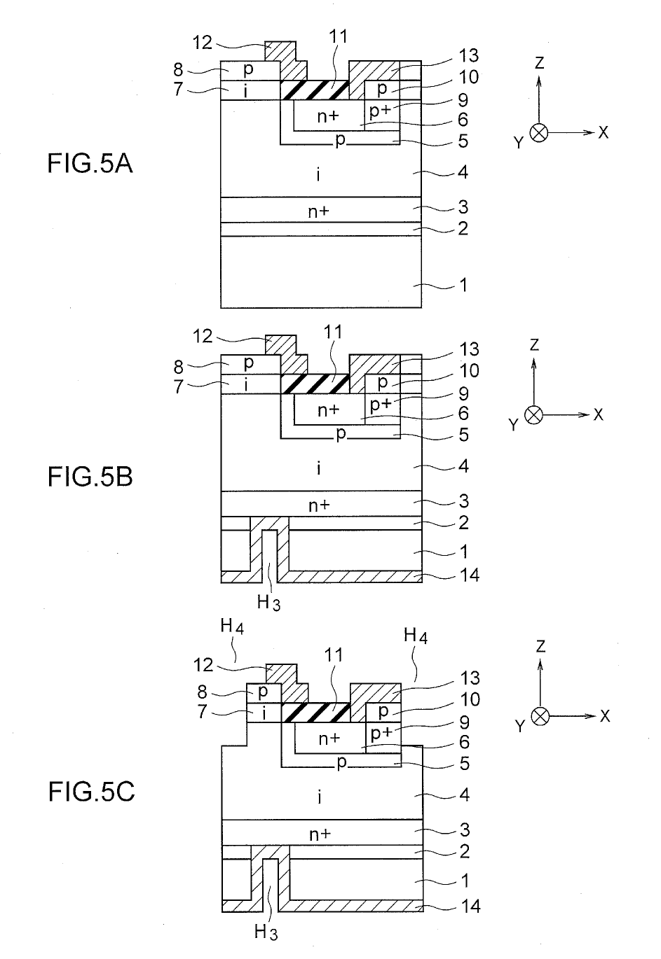

Next, as shown in FIG. 5A, the gate electrode 12 is formed on the first p type semiconductor layer 5 and the second n type contact layer 6 through the gate insulator 11 in a state that areas other than the formation planned area of the gate electrode 12 are covered with resist masks. At this point, the gate electrode 12 is formed also on the second p type semiconductor layer 8, and is electrically connected to the second p type semiconductor layer 8.

Next, as shown in FIG. 5B, an opening H₃ is formed on the substrate 1. The opening H₃ is formed so as to penetrate the substrate 1 and the buffer layer 2 to reach the first n type contact layer 3. Next, the drain electrode 14 is formed on the upper portion and the side portions of the opening H₃ and on the lower portion of the substrate 1. An example of the material of the drain electrode 14 is an ohmic electrode material, and the drain electrode 14 is, for example, a laminated film that includes at least any one of an Al layer, Ti layer, Ni layer, and Au layer.

Next, as shown in FIG. 5C, by means of lithography and etching, openings H₄ used for the element isolation are formed on the substrate 1. Consequently, the vertical transistor is formed on the substrate 1.

Subsequently, the interlayer dielectric 15 is formed on the substrate 1. Furthermore, various interlayer dielectrics, interconnect layers, and the like are formed on the substrate 1. In such a manner, the semiconductor device of the first embodiment can be manufactured.

As described above, the semiconductor device of the present embodiment includes the second n type contact layer 6 on the first electron transport layer 4 through the first p type semiconductor layer 5, and the second p type semiconductor layer 8 on the first electron transport layer 4 through the electron supply layer 7. Therefore, according to the present embodiment, it is possible to deplete a 2DEG layer on an interface between the first electron transport layer 4 and the electron supply layer 7, which consequently enables the vertical transistor using a nitride semiconductor material to exert an operation of an enhancement type.

### Second Embodiment

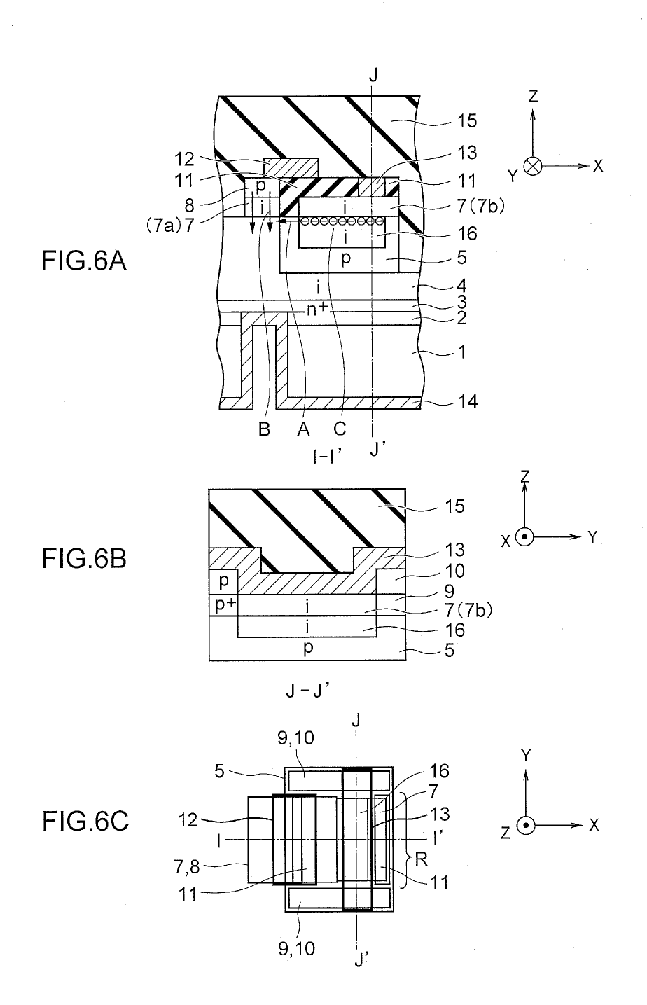

FIGS. 6A to 6C are cross sectional views and a plan view showing a structure of a semiconductor device of a second embodiment.

FIG. 6A is a cross sectional view taken along a line I-I′ in the plan view of FIG. 6C. FIG. 6B is a cross sectional view taken along a line J-J′ in the plan view of FIG. 6C and in the cross sectional view of FIG. 6A. Reference character R in FIG. 6C denotes the operating region of the transistor. In FIG. 6B and FIG. 6C, the illustrations of the substrate 1, the buffer layer 2, the first n type contact layer 3, and the first electron transport layer 4 are omitted.

The electron supply layer 7 of the present embodiment is divided into a first portion 7a and a second portion 7b. The first portion 7a is an example of the fourth semiconductor layer. The second portion 7b is an example of a sixth semiconductor layer. Furthermore, in the present embodiment, the second n type contact layer 6 of the first embodiment is replaced with a second electron transport layer 16. An example of the second electron transport layer 16 is an i type GaN layer. The second electron transport layer 16 is an example of the third semiconductor layer.

The first portion 7a is formed on the first electron transport layer 4. An example of the first portion 7a is an i type AlGaN layer. The second p type semiconductor layer 8 is formed on the first portion 7a.

The second portion 7b is formed on the second electron transport layer 16. An example of the second portion 7b is, as with the first portion 7a, an i type AlGaN layer. The gate insulator 11 is formed on the first p type semiconductor layer 5 and the second portion 7b, and is interposed between the first portion 7a and the second portion 7b. The gate insulator 11 is also in contact with a side portion of the second p type semiconductor layer 8. The gate electrode 12 is formed on the first p type semiconductor layer 5 and the second portion 7b via the gate insulator 11. The gate electrode 12 is formed also on the second p type semiconductor layer 8, and is electrically connected to the second p type semiconductor layer 8. The source electrode 13 is formed on the second portion 7b and the p type source layers 10, and is in contact with the upper portion of the second portion 7b, and the upper portions and the side portions of the p type source layers 10.

In addition, the semiconductor device of the present embodiment includes, as shown in FIG. 6B and FIG. 6C, two sets of the p type contact layers 9 and the p type source layers 10 that are disposed so as to sandwich the operating region R. The p type contact layer 9 and the p type source layer 10 of one of the sets are disposed in a +Y direction with respect to the second portion 7b and the second electron transport layer 16, and the p type contact layer 9 and the p type source layer 10 of the other set are disposed in a −Y direction with respect to the second portion 7b and the second electron transport layer 16. The second electron transport layer 16 and the second portion 7b are disposed between the former set and the latter set.

The second p type semiconductor layer 8 of the present embodiment has a function of raising the potential of a channel on a heterointerface between the first electron transport layer 4 and the first portion 7a. Therefore, when the transistor of the present embodiment is off, an energy level of a conduction band in this heterointerface becomes higher than the Fermi level thereof, and a 2DEG in the channel is depleted. Therefore, the transistor of the present embodiment exerts the operation of the enhancement type.

On the other hand, when the transistor of the present embodiment is turned on, the upper surface of the first p type semiconductor layer 5 below the gate electrode 12 is channelized and brought into a conduction state. Consequently, as shown by an arrow A, electrons flow from the second electron transport layer 16 to the first electron transport layer 4 via the first p type semiconductor layer 5. At the same time, positive holes are led from the second p type semiconductor layer 8 to the above-described heterointerface as shown by arrows B, which generates electrons on the above-described heterointerface. Consequently, electrons flow from the first electron transport layer 4 to the drain electrode 14.

In addition, in the present embodiment, as shown by reference character C, electrons (2DEG) are generated also on a heterointerface between the second electron transport layer 16 and the second portion 7b. These electrons serve as carriers of channel current flowing as shown by the arrow A. Therefore, according to the present embodiment, it is possible to reduce the on-resistance of the transistor more compared with the first embodiment.

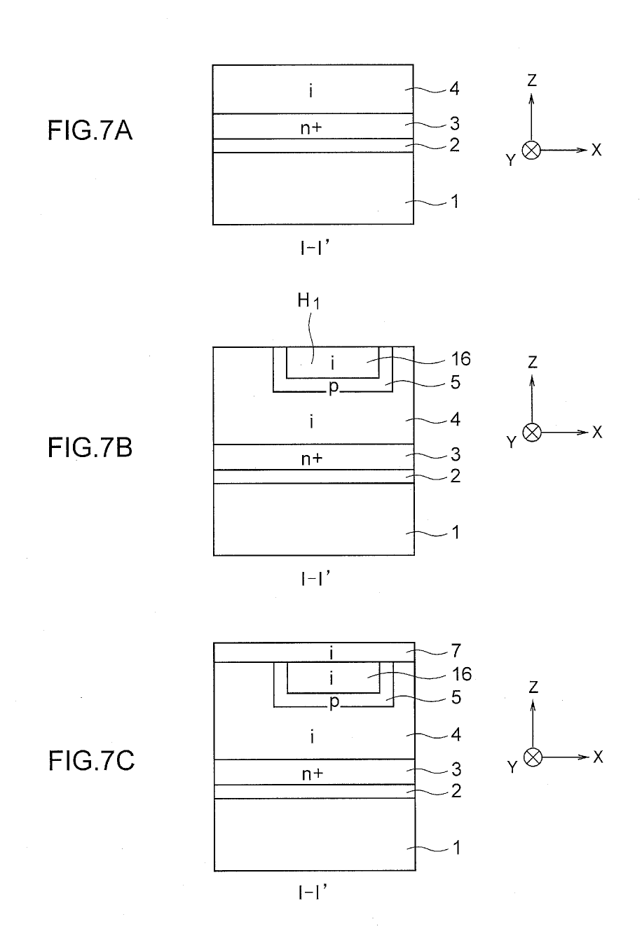

FIGS. 7A to 10B are cross sectional views and plan views showing a method of manufacturing the semiconductor device of the second embodiment.

First, as shown in FIG. 7A, the buffer layer 2, the first n type contact layer 3, and the first electron transport layer 4 are sequentially formed on the substrate 1.

Next, as shown in FIG. 7B, by means of lithography and RIE, an opening H₁ is formed on the first electron transport layer 4. Next, the first p type semiconductor layer 5 is formed on the side portions and the lower portion of the opening H₁. Next, the second electron transport layer 16 is formed in the opening H₁ via the first p type semiconductor layer 5.

Next, as shown in FIG. 7C, the electron supply layer 7 is formed on the first electron transport layer 4, the first p type semiconductor layer 5, and the second electron transport layer 16.

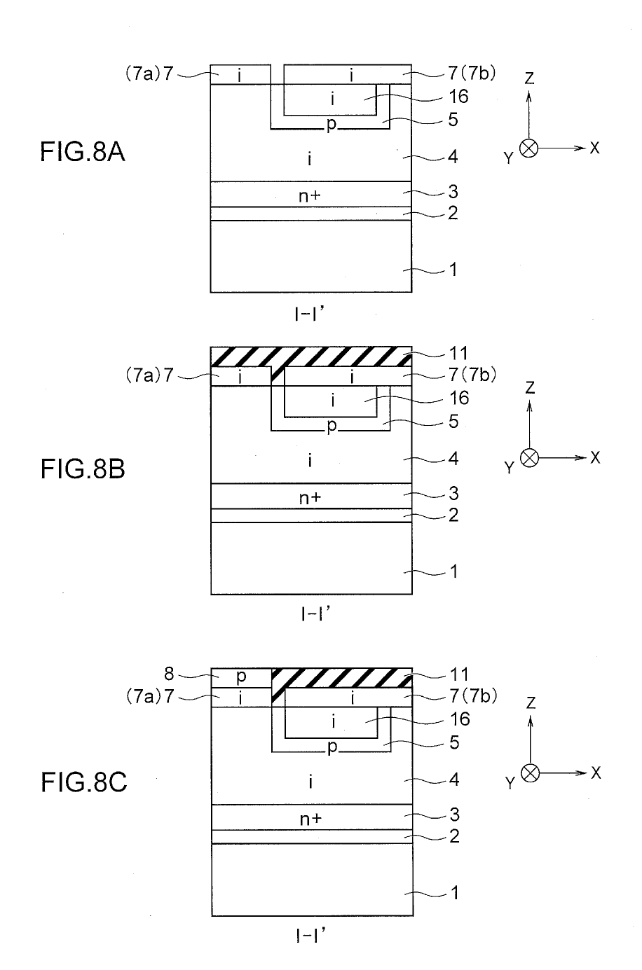

Next, as shown in FIG. 8A, by means of lithography and RIE, the electron supply layer 7 is etched to be divided into the first and second portions 7a and 7b. Consequently, part of the first p type semiconductor layer 5 is exposed through the electron supply layer 7.

Next, as shown in FIG. 8B, the gate insulator 11 is formed on the whole surface of the substrate 1. Consequently, the gate insulator 11 is formed on the exposed first p type semiconductor layer 5 and the electron supply layer 7, and is interposed between the first portion 7a and the second portion 7b.

Next, as shown in FIG. 8C, by means of lithography and RIE, the gate insulator 11 on the first portion 7a is removed to expose the first portion 7a through the gate insulator 11. Next, the second p type semiconductor layer 8 is formed on the exposed first portion 7a.

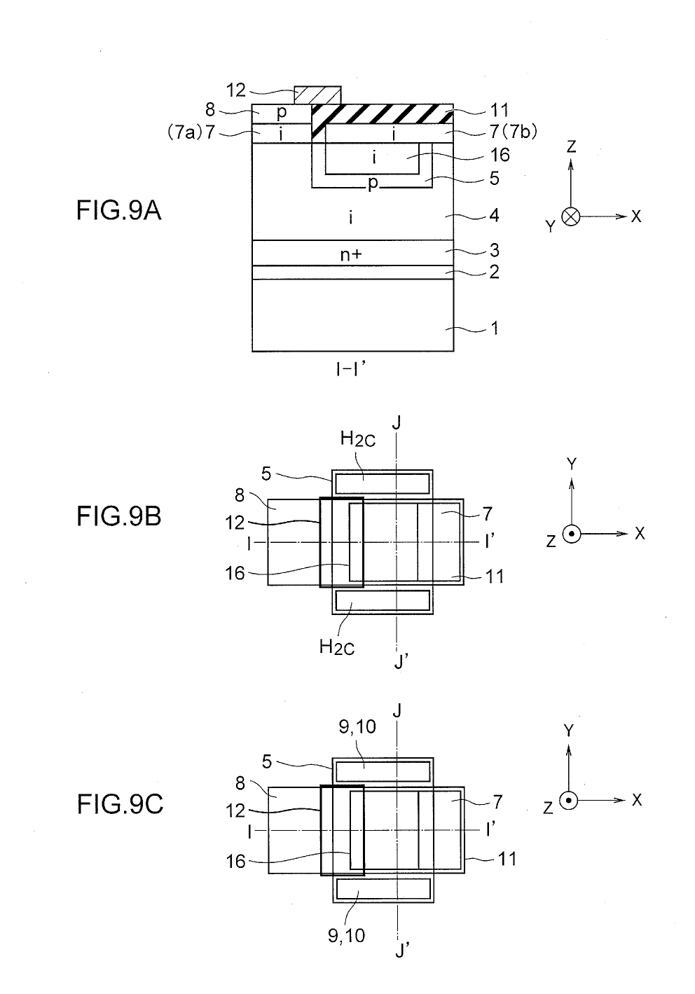

Next, as shown in FIG. 9A, the gate electrode 12 is formed on the first p type semiconductor layer 5 and the second portion 7b via the gate insulator 11. At this point, the gate electrode 12 is formed also on the second p type semiconductor layer 8, and is electrically connected to the second p type semiconductor layer 8.

Next, as shown in FIG. 9B, by means of lithography and RIE, openings H_{2C} that penetrate the gate insulator 11 and the electron supply layer 7 (second portion 7b) in the formation planned areas of the p type contact layers 9 and the p type source layers 10 to reach the first p type semiconductor layer 5, are formed. For the sake of convenience of illustration, the electron supply layer 7, the second p type semiconductor layer 8, the gate insulator 11, and the gate electrode 12 in FIG. 9B are shown only in the operating region R of the transistor.

Next, as shown in FIG. 9C, the p type contact layers 9 and the p type source layers 10 are sequentially formed on the first p type semiconductor layer 5 in the openings H_{2C}. Subsequently, the used resist mask is removed through a liftoff process.

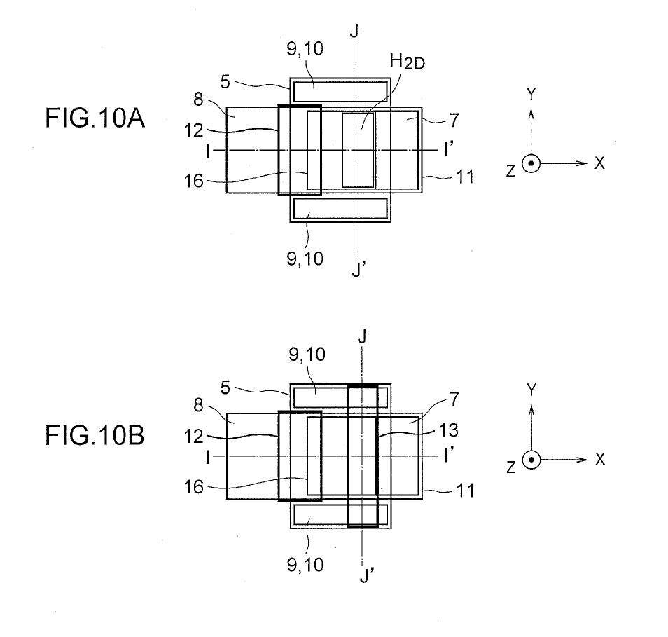

Next, as shown in FIG. 10A, by means of lithography and RIE, an opening H_{2D} that penetrates the gate insulator 11 in the formation planned area of the source electrode 13 to reach the electron supply layer 7 (second portion 7b), is formed.

Next, as shown in FIG. 10B, resist masks are formed on areas other than the formation planned area of the source electrode 13, and the source electrode 13 is formed on the electron supply layer 7 (second portion 7b) and the p type source layers 10 in the opening H_{2D}. Subsequently, the resist masks are removed through a liftoff process.

Next, the processes of FIG. 5B and FIG. 5C are performed. Note that, as shown in FIG. 6A, the element isolation is performed such that the part of the p type semiconductor layer 5 that is in contact with the lower portion of the second portion 7b of the electron supply layer 7 can be left. Consequently, the vertical transistor is formed on the substrate 1. In such a manner, the semiconductor device of the second embodiment can be manufactured.

### Third Embodiment

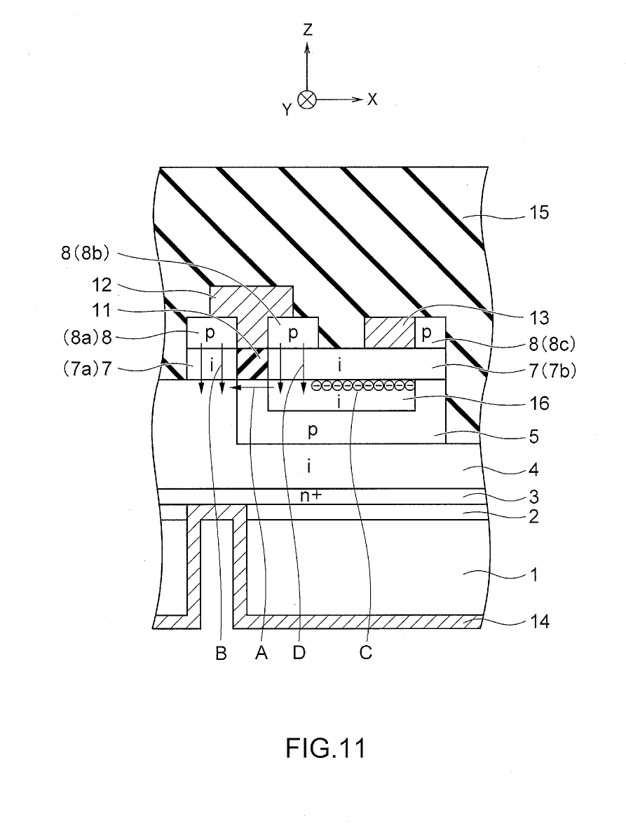

FIG. 11 is a cross sectional view showing a structure of a semiconductor device of a third embodiment.

The electron supply layer 7 of the present embodiment is, as with the second embodiment, divided into the first portion 7a and the second portion 7b. In addition, the second p type semiconductor layer 8 of the present embodiment is divided into a third portion 8a, a fourth portion 8b, and a fifth portion 8c. The third portion 8a is an example of the fifth semiconductor layer. The fourth portion 8b is an example of a seventh semiconductor layer.

The third portion 8a is formed on the first portion 7a, and is in contact with the gate electrode 12. An example of the third portion 8a is a p type AlGaN layer. The third portion 8a of the present embodiment has a function of raising the potential of a channel on a heterointerface between the first electron transport layer 4 and the first portion 7a.

The fourth portion 8b is formed on the second portion 7b, and is in contact with the gate electrode 12. An example of the fourth portion 8b is, as with the third portion 8a, a p type AlGaN layer. The fourth portion 8b of the present embodiment has a function of raising the potential of a channel on a heterointerface between the second electron transport layer 16 and the second portion 7b.

The fifth portion 8c is formed the second portion 7b, and is in contact with the source electrode 13. An example of the fifth portion 8c is, as with the third and fourth portions 8a and 8b, a p type AlGaN layer.

The gate insulator 11 is formed on the first p type semiconductor layer 5, and is interposed between the first portion 7a and the second portion 7b. The gate electrode 12 is formed on the first p type semiconductor layer 5 via the gate insulator 11, and is electrically connected to the third and fourth portions 8a and 8b. The source electrode 13 is formed on the second portion 7b and the p type source layers 10 (not shown), and is in contact with the upper portion of the second portion 7b, the side portions of the fifth portion 8c, and the upper portions and the side portions of the p type source layers 10. The shapes and dispositions of the p type contact layers 9 and the p type source layers 10 of the present embodiment are the same as those of the second embodiment.

The third portion 8a of the present embodiment has a function of raising the potential of a channel on a heterointerface between the first electron transport layer 4 and the first portion 7a. Therefore, when the transistor of the present embodiment is off, an energy level of a conduction band of this heterointerface becomes higher than the Fermi level thereof, and 2DEG in the channel is depleted. This applies also to the heterointerface between the second electron transport layer 16 and the second portion 7b. Consequently, the transistor of the present embodiment exerts the operation of the enhancement type.

On the other hand, when the transistor of the present embodiment is turned on, the upper surface of the first p type semiconductor layer 5 below the gate electrode 12 is channelized to be brought into a conduction state. At the same time, as shown by arrows B and D, positive holes are led from the third and fourth portions 8a and 8b to both the above-described heterointerfaces, which generates electrons on these heterointerfaces. Then, these electrons serve as carriers of current flowing as shown by an arrow A.

In the present embodiment, the 2DEG in the channel is depleted by not only the third portion 8a but also the fourth portion 8b. Therefore, according to the present embodiment, it is possible to enhance the pinch-off property of the transistor as compared with the second embodiment.

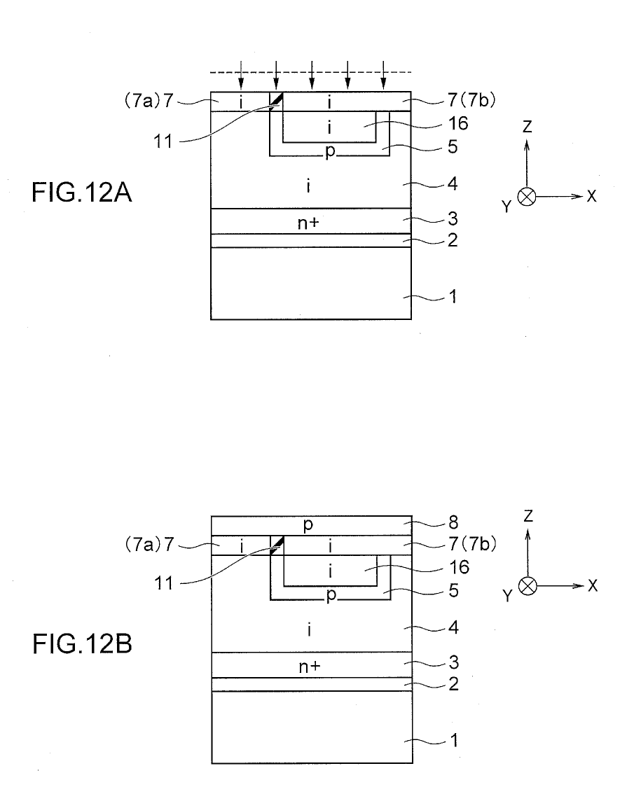

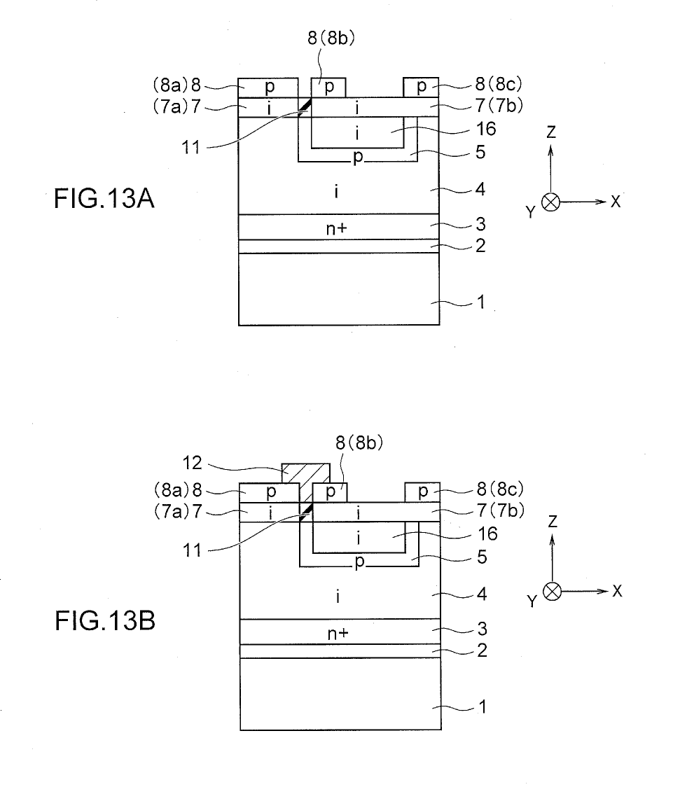

FIGS. 12A to 13B are cross sectional views showing a method of manufacturing the semiconductor device of the third embodiment.

First, the processes of FIGS. 7A to 8B are performed.

Next, as shown in FIG. 12A, the gate insulator 11 is thinned by etching or the like to expose the electron supply layer 7 from the gate insulator 11.

Next, as shown in FIG. 12B, the second p type semiconductor layer 8 is formed on the electron supply layer 7 and the gate insulator 11.

Next, as shown in FIG. 13A, by means of lithography and RIE, the second p type semiconductor layer 8 is etched to be divided into the third, fourth, and fifth portions 8a, 8b, and 8c. Consequently, the gate insulator 11 and part of the electron supply layer 7 are exposed through the second p type semiconductor layer 8.

Next, as shown in FIG. 13B, the gate electrode 12 is formed on the first p type semiconductor layer 5 via the gate insulator 11. At this point, the gate electrode 12 is formed also on the third and fourth portions 8a and 8b, and is electrically connected to the third and fourth portions 8a and 8b.

Next, the processes of FIGS. 9B to 10B are performed. Note that, as shown in FIG. 11, the element isolation is performed such that the part of the p type semiconductor layer 5 that is in contact with the lower portion of the second portion 7b of the electron supply layer 7 can be left. Consequently, the vertical transistor is formed on the substrate 1. In such a manner, the semiconductor device of the third embodiment can be manufactured.

The substrate 1 of the first to third embodiments may be a GaN substrate instead of a silicon substrate. Using a GaN substrate as the substrate 1 offers an advantage in that there is a small difference of lattice constants between the substrate 1 and a nitride semiconductor layer. Therefore, in this case, the opening H₃ does not need to be formed on the back surface of the substrate 1, and the buffer layer 2 is also not necessary.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A semiconductor device comprising:
a first semiconductor layer of a first conductivity type or an intrinsic type;
a second semiconductor layer of a second conductivity type provided on the first semiconductor layer;
a third semiconductor layer of the first conductivity type or an intrinsic type provided on the second semiconductor layer;
a fourth semiconductor layer provided on the first semiconductor layer;
a fifth semiconductor layer of the second conductivity type provided on the fourth semiconductor layer; and
a control electrode provided on the second semiconductor layer through an insulating layer and electrically connected to the fifth semiconductor layer.

2. The device of claim 1, wherein an interface between the first and fourth semiconductor layers is a heterointerface.

3. The device of claim 1, further comprising:
a first electrode provided on the third semiconductor layer; and
a second electrode provided below the first semiconductor layer.

4. The device of claim 1, further comprising a sixth semiconductor layer provided on the third semiconductor layer.

5. The device of claim 4, wherein an interface between the third and sixth semiconductor layers is a heterointerface.

6. The device of claim 4, further comprising:
a first electrode provided on the sixth semiconductor layer; and
a second electrode provided below the first semiconductor layer.

7. The device of claim 4, wherein the insulating layer is provided between the fourth and sixth semiconductor layers and is in contact with a side portion of the fifth semiconductor layer.

8. The device of claim 4, further comprising a seventh semiconductor layer of the second conductivity type provided on the sixth semiconductor layer and electrically connected to the control electrode.

9. The device of claim 8, wherein the control electrode is provided between the fifth and seventh semiconductor layers.

10. The device of claim 3, further comprising:
an eighth semiconductor layer of the second conductivity type in contact with the second and third semiconductor layers; and
a ninth semiconductor layer of the second conductivity type provided on the eighth semiconductor layer,
wherein the first electrode is provided on the ninth semiconductor layer.

11. The device of claim 6, further comprising:
a first set of eighth and ninth semiconductor layers of the second conductivity type sequentially provided on the second semiconductor layer; and
a second set of eighth and ninth semiconductor layers of the second conductivity type sequentially provided on the second semiconductor layer,
wherein the first electrode is provided on the ninth semiconductor layers of the first and second sets, and is provided between the first set of eighth and ninth semiconductor layers and the second set of eighth and ninth semiconductor layers.

12. A method of manufacturing a semiconductor device, comprising:
forming a first semiconductor layer of a first conductivity type or an intrinsic type;
forming a second semiconductor layer of a second conductivity type on the first semiconductor layer;
forming a third semiconductor layer of the first conductivity type or an intrinsic type on the second semiconductor layer;
forming a fourth semiconductor layer on the first semiconductor layer;
forming a fifth semiconductor layer of the second conductivity type on the fourth semiconductor layer; and
forming a control electrode on the second semiconductor layer through an insulating layer such that the control electrode is electrically connected to the fifth semiconductor layer.

13. The method of claim 12, further comprising:
forming a first electrode on the third semiconductor layer; and
forming a second electrode below the first semiconductor layer.

14. The method of claim 12, further comprising forming a sixth semiconductor layer on the third semiconductor layer.

15. The method of claim 14, further comprising:
forming a first electrode on the sixth semiconductor layer; and
forming a second electrode below the first semiconductor layer.

16. The method of claim 14, wherein the fourth and sixth semiconductor layers are formed by dividing a semiconductor layer.

17. The method of claim 14, further comprising forming a seventh semiconductor layer of the second conductivity type on the sixth semiconductor layer,
wherein the control electrode is electrically connected to the seventh semiconductor layer.

18. The method of claim 17, wherein the fifth and seventh semiconductor layers are formed by dividing a semiconductor layer.

19. The method of claim 13, further comprising:
forming an eighth semiconductor layer of the second conductivity type in contact with the second and third semiconductor layers; and
forming a ninth semiconductor layer of the second conductivity type provided on the eighth semiconductor layer,
wherein the first electrode is formed on the ninth semiconductor layer.

20. The method of claim 15, further comprising:
sequentially forming a first set of eighth and ninth semiconductor layers of the second conductivity type on the second semiconductor layer; and
sequentially forming a second set of eighth and ninth semiconductor layers of the second conductivity type on the second semiconductor layer,
wherein the first electrode is formed on the ninth semiconductor layers of the first and second sets, and is formed between the first set of eighth and ninth semiconductor layers and the second set of eighth and ninth semiconductor layers.
